(19) United States
(12) Patent Application Publication
(10) Pub. No.: US 2022/0151069 A1
(43) Pub. Date: May 12, 2022

(54) ANISOTROPIC CONDUCTIVE SHEET, ELECTRICAL INSPECTION APPARATUS, AND ELECTRICAL INSPECTION METHOD

(71) Applicant: Mitsui Chemicals, Inc., Tokyo (JP)

(72) Inventors: Taichi KOYAMA, Yokohama-shi, Kanagawa (JP); Katsunori NISHIURA, Chiba-shi, Chiba (JP); Daisuke YAMADA, Yokohama-shi, Kanagawa (JP)

(21) Appl. No.: 17/434,458

(22) PCT Filed: Feb. 28, 2020
(86) PCT No.: PCT/JP2020/008410

§ 371 Date: Aug. 27, 2021

(30) Foreign Application Priority Data
Feb. 28, 2019 (JP) 2019-036179
May 27, 2019 (JP) 2019-098814
May 27, 2019 (JP) 2019-098816

(51) Int. Cl. H05K 1/11; H05K 3/40; H05K 3/42; H05K 3/38; G01R 1/073

(52) U.S. Cl. CPC H05K 1/115; H05K 3/4069; H05K 3/425; H05K 3/386; H05K 1/0373; H05K 2201/09609; H05K 2201/09827; H05K 2201/09581; H05K 2201/0133; G01R 1/073

(57) ABSTRACT

This anisotropic conductive sheet has: an insulation layer that has a first surface and a second surface and that is formed of a first resin composition; a plurality of resinous columns that are formed of a second resin composition and that are disposed so as to extend in the thickness direction within the insulation layer; and a plurality of conductive layers that are disposed between the insulation layer and the plurality of resinous columns and that are exposed outside the second surface and the first surface.

### TECHNICAL FIELD

The present disclosure relates to an anisotropic conductive sheet, an electrical testing apparatus and an electrical testing method.

### BACKGROUND ART

An anisotropic conductive sheet that has conductivity in the thickness direction and insulation in the surface direction is known. Such an anisotropic conductive sheet is used for various applications, such as a probe (contact) of an electrical testing apparatus for measuring the electrical property between measurement points of an inspection object such as a printed board.

As an anisotropic conductive sheet used for electrical testing, for example, an anisotropic conductive sheet including an insulation layer and a plurality of metal pins disposed to extend through the thickness direction thereof is known (e.g., PTLS 1 and 2).

### CITATION LIST

### Patent Literature

PTL 1
Japanese Patent Application Laid-Open No. H4-17282
PTL 2
Japanese Patent Application Laid-Open No. 2016-213186

### SUMMARY OF INVENTION

### Technical Problem

However, metal pins are exposed at the surfaces of the anisotropic conductive sheets disclosed in PTLS 1 and 2. Consequently, when a terminal of a semiconductor package as an inspection object is aligned on the anisotropic conductive sheets, the terminal of the semiconductor package is easily damaged by making contact with the metal pin exposed from the surface of the anisotropic conductive sheet.

To solve the above-mentioned problems, an object of the present disclosure is to provide an anisotropic conductive sheet, an electrical testing apparatus and an electrical testing method that can suppress the damage of the terminal of the inspection object.

### Solution to Problem

The above-mentioned problems can be solved by the following configurations.

An anisotropic conductive sheet of the present disclosure includes: an insulation layer including a first surface and a second surface, and including a first resin composition; a plurality of columnar resins disposed to extend in a thickness direction in the insulation layer, and comprising a second resin composition; and a plurality of conductive layers disposed between the plurality of columnar resins and the insulation layer, and exposed to outside of the first surface and the second surface.

An electrical testing apparatus of the present disclosure includes: an inspection substrate including a plurality of electrodes; and the above-described anisotropic conductive sheet disposed on a surface of the inspection substrate where the plurality of electrodes is disposed.

An electrical testing method of the present disclosure includes: stacking an inspection substrate including a plurality of electrodes and an inspection object including a terminal through the above-described anisotropic conductive sheet to electrically connect the plurality of electrodes of the inspection substrate and the terminal of the inspection object through the anisotropic conductive sheet.

### Advantageous Effects of Invention

The present disclosure can provide an anisotropic conductive sheet, an electrical testing apparatus and an electrical testing method that can suppress damaging of the terminal of the inspection object.

### BRIEF DESCRIPTION OF DRAWINGS

FIG. 1A is a perspective view illustrating an anisotropic conductive sheet according to Embodiment 1, and FIG. 1B is a partial sectional view taken along line 1B-1B of FIG. 1A;

FIGS. 2A to 2D are partial sectional views illustrating a manufacturing process of the anisotropic conductive sheet according to Embodiment 1;

FIG. 3 is a sectional view illustrating an electrical testing apparatus according to Embodiment 1;

FIGS. 4A and 4B are partial sectional views illustrating an anisotropic conductive sheet according to a modification;

FIGS. 5A and 5B are partial sectional views illustrating an anisotropic conductive sheet according to a modification;

FIG. 6A is a perspective view illustrating an anisotropic conductive sheet according to Embodiment 2, FIG. 6B is a partially enlarged view of the anisotropic conductive sheet illustrated in FIG. 6A taken along a horizontal cross-section, and FIG. 6C is a partially enlarged view of the anisotropic conductive sheet illustrated in FIG. 6A taken along a vertical cross-section;

FIGS. 7A to 7E are partial sectional views illustrating a manufacturing process of the anisotropic conductive sheet according to Embodiment 2;

FIG. 8A is a perspective view illustrating an anisotropic conductive sheet according to Embodiment 3, and FIG. 8B is a partially enlarged view of the anisotropic conductive sheet illustrated in FIG. 8A taken along a vertical cross-section;

FIGS. 9A to 9E are partial sectional views illustrating a manufacturing process of the anisotropic conductive sheet according to Embodiment 3; and

FIG. 10 is a partial sectional view illustrating an anisotropic conductive sheet according to a modification.

### DESCRIPTION OF EMBODIMENTS

Embodiments of the present disclosure are elaborated below with reference to the accompanying drawings.

### Embodiment 1

### 1. Anisotropic Conductive Sheet

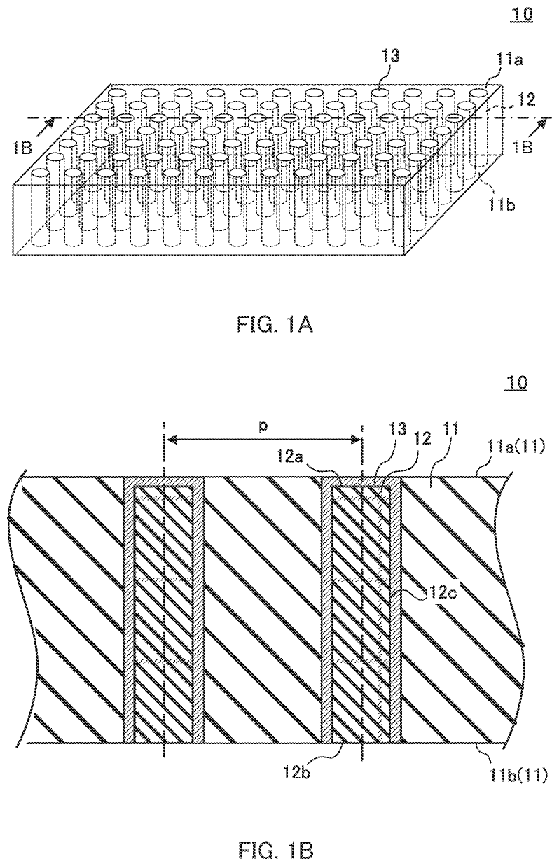

FIG. 1A is a perspective view illustrating anisotropic conductive sheet 10 according to Embodiment 1, and FIG. 1B is a partial sectional view taken along line 1B-1B of FIG. 1A.

As illustrated in FIGS. 1A and 1B, anisotropic conductive sheet 10 includes insulation layer 11, a plurality of columnar resins 12 disposed inside, and a plurality of conductive layers 13 disposed between columnar resin 12 and insulation layer 11.

### 1-1. Insulation Layer 11

Insulation layer 11 is a layer with first surface 11a on one side in the thickness direction and second surface 11b on the other side in the thickness direction, and is composed of a first resin composition (see FIGS. 1A and 1B). Insulation layer 11 insulates between the plurality of conductive layers 13. In the present embodiment, preferably first surface 11a of insulation layer 11 is one surface of anisotropic conductive sheet 10 and second surface 11b of insulation layer 11 is the other surface anisotropic conductive sheet 10, and, an inspection object is disposed on first surface 11a.

The first resin composition constituting insulation layer 11 is not limited as long as it can insulate between the plurality of conductive layers 13. From the viewpoint of suppressing damages on the terminal of the inspection object, it is preferable that the glass transition temperature or storage modulus of the first resin composition constituting insulation layer 11 be the same as or lower than the glass transition temperature or storage modulus of a second resin composition constituting columnar resin 12.

More specifically, preferably, the glass transition temperature of the first resin composition is −40° C. or below, more preferably −50° C. or below. The glass transition temperature of the first resin composition can be measured in accordance with JIS K 7095:2012.

Preferably, the storage modulus of the first resin composition at 25° C. is 1.0×10⁷ Pa or smaller, more preferably 1.0×10⁵ to 1.0×10⁷ Pa, still more preferably, 1.0×10⁵ to 9.0×10⁶ Pa. The storage modulus of the first resin composition can be measured in accordance with JIS K 7244-1:1998/ISO6721-1:1994.

The glass transition temperature and storage modulus of the first resin composition may be adjusted by the amount of filler added and the type of elastomer contained in the resin composition. In addition, the storage modulus of the first resin composition may be adjusted also by the form of the resin composition (e.g., whether it is porous or not).

The first resin composition is not limited as long as it provides insulation, but from the viewpoint of making it easier to meet the glass transition temperature or storage modulus described above, it is preferable to be a cross-linked product of a composition containing an elastomer (base polymer) and a cross-linking agent (hereinafter referred to as “first elastomer composition”). That is, insulation layer 11 may be an elastic body layer composed of a cross-linked product of the first elastomer composition.

Preferable examples of the elastomer include elastomers such as silicone rubber, urethane rubber (urethane polymer), acrylic rubber (acrylic polymer), ethylene-propylene-diene copolymer (EPDM), chloroprene rubber, styrene-butadiene copolymer, acrylic nitrile-butadiene copolymer, poly butadiene rubber, natural rubber, polyester thermoplastic elastomer, and olefin thermoplastic elastomer. Among them, silicone rubber is preferable.

The cross-linking agent may be selected according to the type of elastomer. Examples of cross-linking agents for silicone rubber include organic peroxides such as benzoyl peroxide, bis-2,4-dichlorobenzoyl peroxide, dicumyl peroxide, and di-t-butyl peroxide. Examples of cross-linking agents for acrylic rubbers (acrylic polymers) include epoxy compounds, melamine compounds, and isocyanate compounds.

The first elastomer composition may also further contain other components such as adhesion-imparting agents, silane coupling agents, and fillers as necessary from the viewpoint of facilitating adjustment of adhesion and storage modulus to the above ranges, for example.

The first elastomer composition may be porous from the perspective of facilitating adjustment of the storage modulus to the above range, for example. In other words, porous silicone can be used.

### 1-2. Columnar Resin 12

The plurality of columnar resins 12 are disposed to extend in the thickness direction in insulation layer 11 and composed of the second resin composition (see FIG. 1B). Columnar resin 12 supports conductive layer 13.

Columnar resin 12 extending in the thickness direction of insulation layer 11 means that the axis direction of columnar resin 12 is approximately parallel with the thickness direction of insulation layer 11. The approximately parallel means±10° or smaller with respect to the thickness direction of insulation layer 11. The axis direction means the direction connecting two end surfaces 12a and 12b described later. That is, columnar resin 12 is disposed such that two end surfaces 12a and 12b are located on first surface 11a side and second surface 11b side, respectively.

The shape of columnar resin 12 is not limited, and may be prismatic or cylindrical. In the present embodiment, it has a cylindrical shape.

Columnar resin 12 may be exposed to the outside of insulation layer 11 on at least one of first surface 11a side and second surface 11b side. That is, the surface (end surface 12a) of columnar resin 12 on first surface 11a side may be exposed to first surface 11a side, or the surface (end surface 12b) of columnar resin 12 on second surface 11b side may be exposed to second surface 11b side. In the present embodiment, end surface 12b of columnar resin 12 is exposed to second surface 11b side (see FIG. 1B).

In the case where end surface 12a (or end surface 12b) of columnar resin 12 is exposed to first surface 11a side (or second surface 11b side), end surface 12a (or end surface 12b) of columnar resin 12 may be flush with first surface 11a (or second surface 11b) of insulation layer 11, or may protrude than first surface 11a (or second surface 11b) of insulation layer 11.

End surfaces 12a and 12b of columnar resin 12 may be a flat surface or a curved surface. In the present embodiment, each of end surfaces 12a and 12b of columnar resin 12 is a flat surface (see FIG. 1B).

The cross-sectional area of columnar resin 12 may be constant or vary in the thickness direction of insulation layer 11 (or the axis direction of columnar resin 12). The cross-sectional area means the area of the cross section perpendicular to the axis direction of columnar resin 12. That is, the area of end surface 12a and the area of end surface 12b of columnar resin 12 may be the same or different from each other. In the present embodiment, the area of end surface 12a and the area of end surface 12b of columnar resin 12 are the same. The area of end surface 12a (or end surface 12b) of columnar resin 12 means the area of end surface 12a (or end surface 12b) as viewed along the thickness direction of insulation layer 11.

The circle equivalent diameter of end surface 12a of columnar resin 12 is not limited as long as center-to-center distance p of the plurality of columnar resins 12 can be adjusted in the range described later and conduction between the terminal of the inspection object and conductive layer 13 can be ensured. Preferably, the circle equivalent diameter of end surface 12a of columnar resin 12 is 2 to 20 μm, for example. The circle equivalent diameter of end surface 12a of columnar resin 12 means the circle equivalent diameter of end surface 12a as viewed along the thickness direction of insulation layer 11.

In addition, the circle equivalent diameter of end surface 12a of columnar resin 12 may be the same as the circle equivalent diameter of end surface 12b (see FIG. 1B), or smaller than the circle equivalent diameter of end surface 12b.

Center-to-center distance (pitch) p of the plurality of columnar resins 12 on first surface 11a side is not limited, and may be appropriately set in accordance with the pitch of the terminal of the inspection object. The pitch of the terminal of a high bandwidth memory (HBM) serving as an inspection object is 55 μm, and the pitch of the terminal of a package on package (PoP) is 400 to 650 μm, and therefore, center-to-center distance (pitch) p of the plurality of columnar resins 12 may be 5 to 650 μm, for example. In particular, preferably, center-to-center distance p of the plurality of columnar resins 12 on first surface 11a side is 5 to 55 μm from the viewpoint of eliminating the need of alignment of the terminal of the inspection object (alignment free). Center-to-center distance (pitch) p of the plurality of columnar resins 12 on first surface 11a side means a minimum value of the center-to-center distance of the plurality of columnar resins 12 on first surface 11a side. The center of columnar resin 12 is the center of gravity of end surface 12a.

Center-to-center distance p of the plurality of columnar resins 12 on first surface 11a side may be the same as or different from center-to-center distance p of the plurality of columnar resins 12 on second surface 11b side. In the present embodiment, center-to-center distance p of the plurality of columnar resins 12 on first surface 11a side is the same as center-to-center distance p of the plurality of columnar resins 12 on second surface 11b side.

The second resin composition constituting columnar resin 12 may or may not be the same as the first resin composition constituting insulation layer 11 as long as it can stably support conductive layer 13. Even in the case where the second resin composition constituting columnar resin 12 and the first resin composition constituting insulation layer 11 are the same, columnar resin 12 and insulation layer 11 can be discriminated from each other by, for example, confirming the boundary line between columnar resin 12 and insulation layer 11 and the like in the cross-section of anisotropic conductive sheet 10. In particular, preferably, the glass transition temperature or storage modulus of the second resin composition constituting columnar resin 12 is the same as or higher than the glass transition temperature or storage modulus of the first resin composition constituting insulation layer 11 from the viewpoint of easily and stably supporting conductive layer 13.

That is, preferably, the glass transition temperature of the second resin composition is 120° C. or above, more preferably 150 to 500° C., still more preferably 150 to 200° C. The glass transition temperature of the second resin composition can be measured by the same method as that described above.

Preferably, the storage modulus of the second resin composition at 25° C. is 1.0×10⁶ to 1.0×10¹⁰ Pa, more preferably 1.0×10⁸ to 1.0×10¹⁰ Pa. The storage modulus of the second resin composition can be measured by the same method as that described above.

The glass transition temperature and storage modulus of the second resin composition may be adjusted by the type of the resin or elastomer contained in the resin composition, addition of a filler and the like. In addition, the storage modulus of the second resin composition may be adjusted also by the form (whether it is porous or not) of the resin composition.

The second resin composition may be a cross-linked product of a composition (hereinafter also referred to as “second elastomer composition”) containing an elastomer and a crosslinking agent, or a resin composition containing a resin that is not an elastomer. In particular, from the viewpoint of easily achieving the above-mentioned glass transition temperature or storage modulus, or achieving a strength that can stably support conductive layer 13, it is preferable that the second resin composition be a resin composition containing a resin that is not an elastomer.

Examples of the resin that is not an elastomer include engineering plastics such as polyamide, polycarbonate, polyethylene naphthalate, polyarylate, polysulfone, polyether sulfone, polyphenylene sulfide, polyetheretherketone, polyimide, polyetherimide, and polyamide imide, conductive resins such as poly acetylene and polythiadyl, photosensitive resins such as photosensitive polybenzoxazole and photosensitive polyimide, acrylic resins, urethane resins, epoxy resins, and olefin resins. Preferably, the resin that is not an elastomer is polyimide, polyethylene naphthalate, acrylic resin, or epoxy resin. Of these resins, the resins (curable resins such as epoxy resins) having functional groups that react with curing agents may be cured using a curing agent. That is, the second resin composition may be a cured product of a resin composition containing a curable resin that is not an elastomer and a curing agent.

The second resin composition may further contain other components such as a conductive agent and a filler. A conductive agent may impart conductivity to the second resin composition. Thus, when columnar resin 12 is composed of the second resin composition having conductivity, minimum conductivity can be ensured even if a part of conductive layer 13 is peeled off. Examples of the conductive agent include metal particles and carbon materials (such as carbon black and carbon fiber). Alternatively, the second resin composition may be composed of the above-mentioned resin without containing other components.

### 1-3. Conductive Layer 13

Conductive layer 13 is disposed at least at a part between columnar resin 12 and insulation layer 11, and exposed to the outside of insulation layer 11 on first surface 11a side and second surface 11b side (see FIG. 1B).

More specifically, conductive layer 13 is disposed in such a manner as to be exposed on both first surface 11a side and second surface 11b side, and to conduct between first surface 11a side and second surface 11b side. When conductive layer 13 is disposed in such a manner, conductive layer 13 may be disposed at a part of side surface 12c (the surface extending in the axis direction of columnar resin 12, or the surface connecting end surface 12a and end surface 12b) of columnar resin 12. From the viewpoint of ensuring sufficient conduction, it is preferable that conductive layer 13 be disposed to surround side surface 12c of columnar resin 12, and it is more preferable that it is disposed over the entire side surface 12c of columnar resin 12. In the present embodiment, conductive layer 13 is disposed over the entire side surface 12c of columnar resin 12 (see FIG. 1B).

Preferably, conductive layer 13 is further disposed on at least one of end surfaces 12a and 12b of columnar resin 12. When conductive layer 13 is further disposed on end surface 12a of columnar resin 12, it is easily electrically connected to the terminal of the inspection object when the inspection object is disposed on first surface 11a, and thus sufficient conduction is easily achieved. When conductive layer 13 is further disposed on end surface 12b of columnar resin 12, conductive layer 13 and the electrode of the inspection substrate are easily electrically connected to each other, and thus sufficient conduction is easily achieved. In the present embodiment, conductive layer 13 is further disposed on end surface 12a of columnar resin 12 (see FIG. 1B).

Preferably, for example, the volume resistivity of conductive layer 13 is 1.0×10⁻⁴ m or smaller, more preferably 1.0×10⁻⁶ to 1.0×10⁻⁹ Ω·m while it is not limited as long as sufficient conduction can be achieved. The volume resistivity of conductive layer 13 can be measured by the method described in ASTM D 991.

Regarding the material of conductive layer 13, it suffices that the volume resistivity meets the above-mentioned range. Examples of the material of conductive layer 13 include metal materials such as copper, gold, nickel, tin, and iron and an alloy of one of them, and carbon materials such as carbon black.

Normally, the thickness of conductive layer 13 may be smaller than the circle equivalent diameter of columnar resin 12 while it is not limited as long as the volume resistivity is set to meet the above-mentioned range. For example, the thickness of conductive layer 13 may be 0.1 to 5 μm. Sufficient conduction is easily achieved when conductive layer 13 has a predetermined thickness or greater, whereas damaging of the terminal of the inspection object due to the contact with conductive layer 13 can be easily suppressed when conductive layer 13 has a predetermined thickness or smaller. Note that the thickness of conductive layer 13 is the thickness in a direction orthogonal to the thickness direction of insulation layer 11 (or in the radial direction of columnar resin 12).

The thickness of conductive layer 13 on end surface 12a of columnar resin 12 and the thickness of conductive layer 13 on side surface 12c may be the same or different from each other. For example, the thickness of conductive layer 13 on end surface 12a of columnar resin 12 may be smaller than the thickness of conductive layer 13 on side surface 12c.

Anisotropic conductive sheet 10 according to the present embodiment may further include layers other than the above-mentioned layers as necessary. For example, an electrolyte layer (not illustrated in the drawing) may be further disposed on conductive layer 13 disposed at end surface 12a of columnar resin 12 (conductive layer 13 exposed to first surface 11a side).

### Electrolyte Layer

The electrolyte layer is, for example, a coating containing a lubricant, and may be disposed on conductive layer 13 disposed at end surface 12a of columnar resin 12. Thus, when the inspection object is disposed on first surface 11a, the deformation of the terminal of the inspection object can be suppressed and adhesion of the electrode material of the inspection object to the surface of conductive layer 13 can be suppressed without impairing the electrical connection with the terminal of the inspection object. Note that the electrolyte layer may be disposed not only on conductive layer 13 disposed at end surface 12a of columnar resin 12, but also over the entire surface of anisotropic conductive sheet 10 on the first surface 11a side.

Examples of lubricants in the electrolyte layer include fluoropolymer-based lubricants; lubricants based on inorganic materials such as boron nitride, silica, zirconia, silicon carbide, and graphite; hydrocarbon-based mold-releasing agents such as paraffin waxes, metallic soaps, natural and synthetic paraffins, polyethylene waxes, and fluorocarbons; fatty acid-based mold-releasing agents such as stearic acid, hydroxystearic acid, and other high-grade fatty acids and oxyfatty acids; fatty acid amide release agents such as stearic acid amides, fatty acid amides such as ethylene bis-stearoamide, and alkylene bis-fatty acid amides; alcohol-based release agents such as aliphatic alcohols such as stearyl alcohol and cetyl alcohol, polyhydric alcohols, polyglycols, and polyglycerols; fatty acid ester-based release agents such as aliphatic acid lower alcohol esters such as butyl stearate and pentaerythritol tetrastearate, fatty acid polyhydric alcohol esters, and fatty acid polyglycol esters; silicone based release agents such as silicone oils; and alkyl sulfonate metal salts. Among them, alkyl sulfonate metal salts are preferred from the viewpoint that they have fewer adverse effects such as contaminating the electrodes of the inspection object, especially when used at high temperatures.

Metal salts of alkylsulfonic acids are preferably alkali metal salts of alkylsulfonic acids. Examples of alkali metal salts of alkylsulfonic acids include sodium 1-decanesulfonate, sodium 1-undecanesulfonate, sodium 1-dodecanesulfonate, sodium 1-tridecane sulfonate, sodium 1-tetradecane sulfonate, sodium 1-pentadecane sulfonate, sodium 1-hexadecane sulfonate, sodium 1-heptadecane sulfonate, sodium 1-octadecane sulfonate, sodium 1-nonadecane sulfonate, sodium 1-eicosane sulfonate, potassium 1-decane sulfonate, potassium 1-undecane sulfonate, potassium 1-dodecane sulfonate, potassium 1-tridecane sulfonate, potassium 1-tetradecane sulfonate, potassium 1-pentadecane sulfonate potassium, potassium 1-hexadecane sulfonate, potassium 1-heptadecane sulfonate, potassium 1-octadecane sulfonate, potassium 1-nonadecane sulfonate, potassium 1-eicosanesulfonate, lithium 1-decane sulfonate, lithium 1-undecane sulfonate, lithium 1-dodecane sulfonate, lithium 1-tridecane sulfonate, lithium 1-tetradecane sulfonate, lithium 1-pentadecane sulfonate, lithium 1-hexadecane sulfonate, lithium 1-heptadecanesulfonate, lithium 1-octadecanesulfonate, lithium 1-nonadecanesulfonate, lithium 1-eicosanesulfonate, and their isomers. Among them, the sodium salt of alkylsulfonic acid is particularly preferred because of its excellent heat resistance. These may be used alone or in combination.

The electrolyte layer may further include conductive agents described above as necessary. Note that even when the electrolyte layer does not contain conductive agents, the conductivity can be ensured by disposing the electrolyte layer on conductive layer 13 disposed on end surface 12a of columnar resin 12, and reducing the thickness of the electrolyte layer as much as possible.

### Other Notes

The thickness of anisotropic conductive sheet 10 may be, for example, 20 to 100 μm while it is not limited as long as the insulation property at the non-conduction portion can be ensured.

### Operation

Anisotropic conductive sheet 10 according to the present embodiment includes conductive layer 13 disposed on side surface 12c of columnar resin 12 with a suitable flexibility in place of known metal pins. In this manner, even when the terminal of the inspection object anisotropic makes contact with conductive layer 13 of conductive sheet 10, resulting damages can be suppressed.

### 2. Manufacturing Method of Anisotropic Conductive Sheet

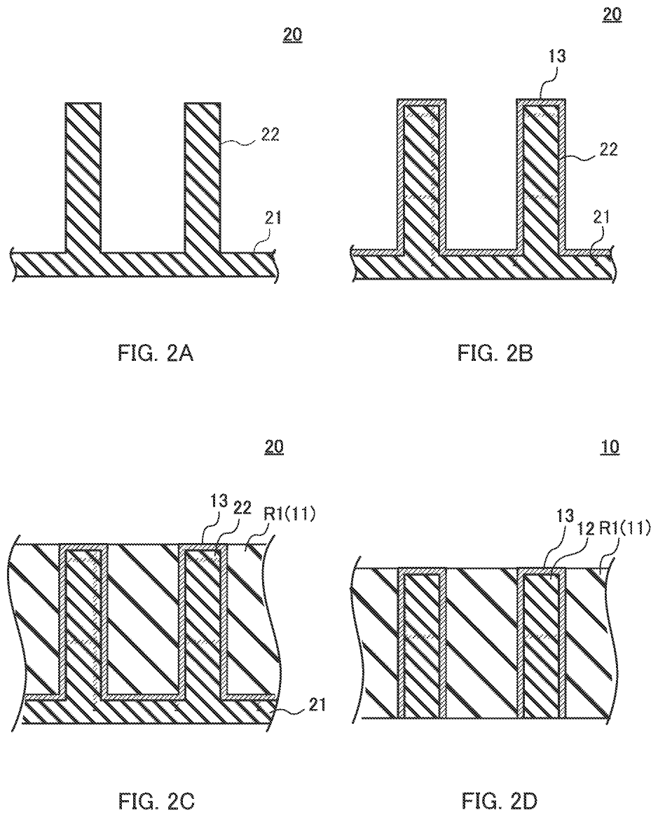

FIGS. 2A to 2D are partial sectional views illustrating a manufacturing process of anisotropic conductive sheet 10 according to the present embodiment.

As illustrated in FIGS. 2A to 2D, anisotropic conductive sheet 10 according to the present embodiment is obtained through 1) a step of preparing resin base material 20 including supporting part 21 and a plurality of column parts 22 disposed on its one surface, and composed of the second resin composition or its precursor (see FIG. 2A), 2) a step of forming conductive layer 13 on the surface of column part 22 (see FIG. 2B), 3) a step of forming insulation layer 11 by filling the space between the plurality of column parts 22 with first resin composition R1 (see FIG. 2C), and 4) a step of removing supporting part 21 of resin base material 20 (see FIG. 2D).

### Step 1)

Resin base material 20 including supporting part 21 and the plurality of column parts 22 disposed on its one surface is prepared (see FIG. 2A).

The plurality of column parts 22 of resin base material 20 is a member that serves as columnar resin 12 of anisotropic conductive sheet 10. Therefore, the sizes, shapes and center-to-center distance of the plurality of column parts 22 may be the same as the sizes, shapes and center-to-center distance of the plurality of columnar resins 12.

Resin base material 20 can be obtained through any methods. For example, resin base material 20 can be obtained by a method (photoresist method) of forming the plurality of column parts 22 in which a photomask is disposed on a resin sheet and it is exposed to light in a pattern through the photomask, and then, unnecessary parts are removed (developed); a method (cutting method) of forming the plurality of column parts 22 in which, for example, a resin plate is cut and processed by a laser; or a method (metal molding or mold-transfer method) of forming the plurality of column parts 22 in which a metal mold is filled with a resin composition, or a transfer surface of a metal mold is pressed against a resin sheet.

For example, in the photoresist method, the resin sheet may be composed of a photosensitive resin composition that is a precursor of the second resin composition. Examples of the photosensitive resin composition include positive-type photosensitive resin compositions such as a mixture of novolak epoxy resin and o-naphthoquinone diazide compound (photosensitizer) and a mixture of acrylic resin and photoacid generator; and negative-type photosensitive resin compositions such as curable compositions containing alkali soluble acrylic resin, multifunctional acrylate (crosslinking agent) and photoinitiator, and curable compositions containing a photosensitive polyimide or photosensitive polybenzoxazole and photoinitiator or crosslinking agent.

The photomask is disposed in a pattern on a resin sheet, for example. Exposure light may be an ultraviolet ray, X ray, electron beam, laser or the like.

The removal (development) of unnecessary parts may be dry etching using reactive gas such as plasma, or wet etching using chemical liquid such as alkali aqueous solution. It suffices to remove the exposure part in the case where the resin sheet is composed of a positive-type photosensitive resin composition, whereas it suffices to remove the non-exposure part in the case where it is composed of a negative-type photosensitive resin composition.

### Step 2)

Next, conductive layer 13 is formed at the surface of column part 22 (see FIG. 2B).

Conductive layer 13 may be formed by any methods. For example, conductive layer 13 may be formed by a plating method (such as an electroless plating method), or may be formed by immersing column part 22 in a conductive paste, or applying a conductive paste.

### Step 3)

Insulation layer 11 is formed at the space between the plurality of column parts 22 (see FIG. 2C).

More specifically, the space between the plurality of column parts 22 is filled with the first elastomer composition (a precursor of the first resin composition). The first elastomer composition may be provided by any methods, such as a dispenser.

Next, the first elastomer composition is dried or heated to crosslink the first elastomer composition. In this manner, insulation layer 11 composed of a cross-linked product of the first elastomer composition (the first resin composition) is formed.

### Step 4)

Then, anisotropic conductive sheet 10 is obtained by removing supporting part 21 of resin base material 20 (see FIG. 2D).

Supporting part 21 may be removed by any methods. For example, supporting part 21 can be removed by cutting supporting part 21 using a laser and the like.

Other Steps

The manufacturing method of anisotropic conductive sheet 10 according to the present embodiment may further include steps other than the above-mentioned steps 1) to 4) in accordance with the configuration of anisotropic conductive sheet 10. For example, it is possible to further include 5) a step of forming the electrolyte layer on conductive layer 13 disposed at end surface 12a of columnar resin 12 (or on end surface 12a). Step 5) may be performed between step 3) and step 4), or after step 4), for example.

The electrolyte layer may be formed by any methods, and, for example, it can be formed by a method of applying the solution of the electrolyte layer. The method of applying the solution of the electrolyte layer may be a publicly known method such as spraying, brushing, dropping electrolyte layer solutions, and dipping the anisotropic conductive sheet 10 into the solution.

In these application methods, it is possible to appropriately utilize a method in which the material of the electrolyte layer is diluted with a solvent such as alcohol, and the diluted solution (the solution of the electrolyte layer) is applied to the surface of anisotropic conductive sheet 10 (conductive layer 13), and then, the solvent is evaporated. In this manner, the electrolyte layer can be uniformly formed at the surface of anisotropic conductive sheet 10 (on conductive layer 13).

In addition, in a case where a material of the electrolyte layer that is in solid powder state at normal temperature is used, it is possible to use a method in which an appropriate amount of the material is disposed on the surface of anisotropic conductive sheet 10, and then anisotropic conductive sheet 10 is heated to a high temperature to melt and apply the material.

### 3. Electrical Testing Apparatus and Electrical Testing Method

### Electrical Testing Apparatus

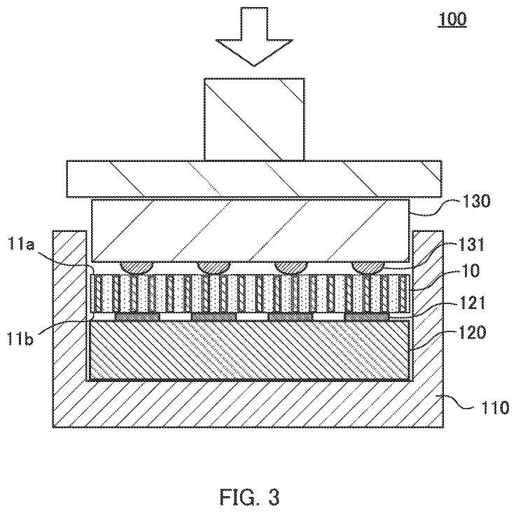

FIG. 3 is a sectional view illustrating an exemplary electrical testing apparatus 100 according to the present embodiment.

Electrical testing apparatus 100 uses anisotropic conductive sheet 10 illustrated in FIG. 1B, and is, for example, an apparatus for inspecting the electrical property (such as conduction) between terminals 131 (the measurement points) of inspection object 130. Note that in this drawing, inspection object 130 is also illustrated from the viewpoint of describing the electrical testing method.

As illustrated in FIG. 3, electrical testing apparatus 100 includes holding container (socket) 110, inspection substrate 120, and anisotropic conductive sheet 10.

Holding container (socket) 110 is a container that holds inspection substrate 120, anisotropic conductive sheet 10 and the like.

Inspection substrate 120 is disposed in holding container 110, and provided with a plurality of electrodes 121 that faces the measurement points of inspection object 130 on the surface that faces inspection object 130.

Anisotropic conductive sheet 10 is disposed on the surface on which electrode 121 of inspection substrate 120 is disposed such that the electrode 121 and conductive layer 13 on second surface 11b side in anisotropic conductive sheet 10 are in contact with each other.

Inspection object 130 is not limited, but is, for example, various semiconductor apparatuses (semiconductor packages) such as HBM and PoP, electronic components, printed boards and the like. In the case where inspection object 130 is a semiconductor package, the measurement point may be a bump (terminal). In addition, in the case where inspection object 130 is a printed board, the measurement point may be a component mounting land or a measurement land provided in the conductive pattern.

### Electrical Testing Method

An electrical testing method using electrical testing apparatus 100 illustrated in FIG. 3 is described below.

As illustrated in FIG. 3, the electrical testing method according to the present embodiment includes a step of electrically connecting electrode 121 of inspection substrate 120 and terminal 131 of inspection object 130 through anisotropic conductive sheet 10 by stacking inspection substrate 120 including electrode 121 and inspection object 130 with anisotropic conductive sheet 10 therebetween.

When performing the above-mentioned step, inspection object 130 may be pressurized by pressing it (see FIG. 3), or they may be brought into contact with each other under a heating atmosphere as necessary from the viewpoint of achieving sufficient conduction between electrode 121 of inspection substrate 120 and terminal 131 of inspection object 130 through anisotropic conductive sheet 10.

In the above-mentioned step, the surface (first surface 11a) of anisotropic conductive sheet 10 makes contact with terminal 131 of inspection object 130.

Anisotropic conductive sheet 10 is conducted by conductive layer 13 disposed on columnar resin 12 with suitable flexibility, not by conventional hard metal pins. Thus, even when terminal 131 of inspection object 130 makes contact with anisotropic conductive layer 13 of conductive sheet 10, resulting damages can be suppressed.

### 3. Modification

Note that while anisotropic conductive sheet 10 illustrated in FIG. 1B is described in the present embodiment, this is not limitative.

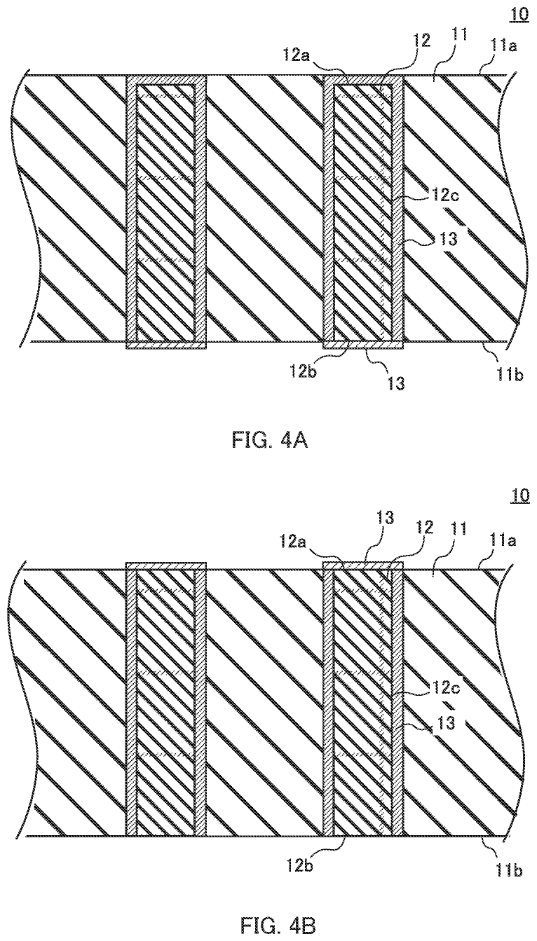

FIGS. 4A and 4B are partial sectional views illustrating anisotropic conductive sheet 10 according to a modification.

As illustrated in FIG. 4A, conductive layer 13 may be disposed not only on end surface 12a of columnar resin 12, but also on end surface 12b. In addition, as illustrated in FIG. 4B, conductive layer 13 may be further disposed on end surface 12a (exposed to first surface 11a side) of columnar resin 12. In this manner, conductive layer 13 disposed on end surface 12a of columnar resin 12 may be protruded than first surface 11a of insulation layer 11.

In FIGS. 4A and 4B, conductive layer 13 disposed on end surface 12a or 12b of columnar resin 12 may be a member integrated with or separated from conductive layer 13 disposed on side surface 12c of columnar resin 12. In addition, the composition of conductive layer 13 disposed on end surface 12a or 12b of columnar resin 12 may be the same as, or different from the composition of conductive layer 13 disposed on side surface 12c of columnar resin 12. For example, conductive layer 13 disposed on end surface 12a or 12b of columnar resin 12 may be a coating film of a conductive paint (a conductive paste containing metal particles of a nanometer level or conductive filler), and conductive layer 13 disposed on side surface 12c of columnar resin 12 may be a layer formed of electroless plating, for example.

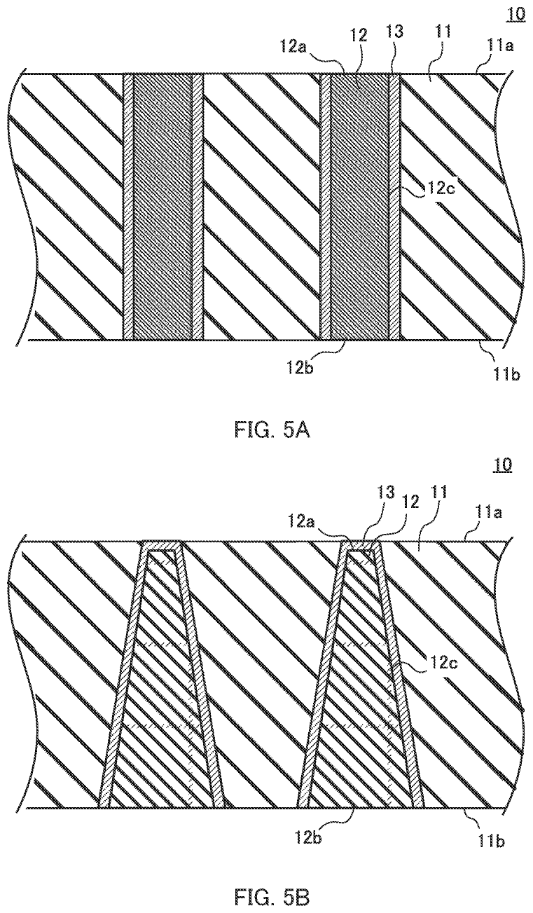

FIGS. 5A and 5B are partial sectional views illustrating anisotropic conductive sheet 10 according to a modification.

As illustrated in FIG. 5A, in the case where the second resin composition constituting columnar resin 12 contains a conductive agent (or is a conductive resin composition), end surface 12a of columnar resin 12 may be exposed to first surface 11a side, and end surface 12b may be exposed to second surface 11b side. The conductive resin composition may be a resin composition containing the above-described resin and conductive agent, or may be a conductive resin.

In addition, as illustrated in FIG. 5A, in the case where end surface 12a of columnar resin 12 is exposed to first surface 11a side, the above-described electrolyte layer (not illustrated in the drawing) may be further disposed on the exposed end surface 12a of columnar resin 12.

As illustrated in FIG. 5B, the area of end surface 12a of columnar resin 12 may be smaller than the area of end surface 12b. Columnar resin 12 may be configured such that the cross-sectional area of columnar resin 12 continuously (gradually) increases, or non-continuously increases, in the direction from first surface 11a side toward second surface 11b side. In this diagram, columnar resin 12 is configured such that the cross-sectional area continuously increases (in a tapered shape) in the direction from first surface 11a side toward second surface 11b side.

In the case where columnar resin 12 has a tapered shape (tapered part), it is preferable that taper ratio C be greater than 0 and 0.1 or smaller. The taper ratio is represented by the following equation.

C=(D2−D1)/L

(where D2: the circle equivalent diameter of the cross-section (or end surface 12b) of the end portion of the tapered part of columnar resin 12 on second surface 11b side,

D1: the circle equivalent diameter of the cross-section (or end surface 12a) of the end portion of the tapered part of columnar resin 12 on first surface 11a side, and

L: the distance between the end portion of the tapered part on first surface 11a side and the end portion of the tapered part on second surface 11b side in the axis direction)

In this manner, the area of conductive layer 13 exposed to first surface 11a side on which the inspection object is disposed can be set to a small area, and damaging of the terminal of the inspection object due to the contact with conductive layer 13 can be further suppressed. In particular, in the case where the storage modulus of the second resin composition constituting columnar resin 12 is higher than the storage modulus of the first resin composition constituting insulation layer 11, damaging of the terminal of the inspection object due to the contact with conductive layer 13 can be further suppressed.

In addition, while insulation layer 11 is composed of the first resin composition in the present embodiment, this is not limitative. It suffices that insulation layer 11 has an elasticity with which it is elastically deformed when a pressure is applied in the thickness direction. Therefore, it suffices that insulation layer 11 includes an elastic body layer composed of a cross-linked product of the first elastomer composition, and other layers may be further provided as long as the elasticity is not impaired in its entirety.

In addition, while electrical testing is performed by pressing inspection object 130 to inspection substrate 120 where anisotropic conductive sheet 10 is disposed in the present embodiment, this is not limitative, and electrical testing may be performed by pressing inspection substrate 120 where anisotropic conductive sheet 10 is disposed to inspection object 130.

In addition, while the anisotropic conductive sheet is used for electrical testing in the present embodiment, this is not limitative, and it may be used for an electrical connection between two electronic members, such as an electrical connection between a glass substrate and a flexible printed board and an electrical connection between a substrate and an electronic component mounted on it.

### Embodiment 2

### 1. Anisotropic Conductive Sheet

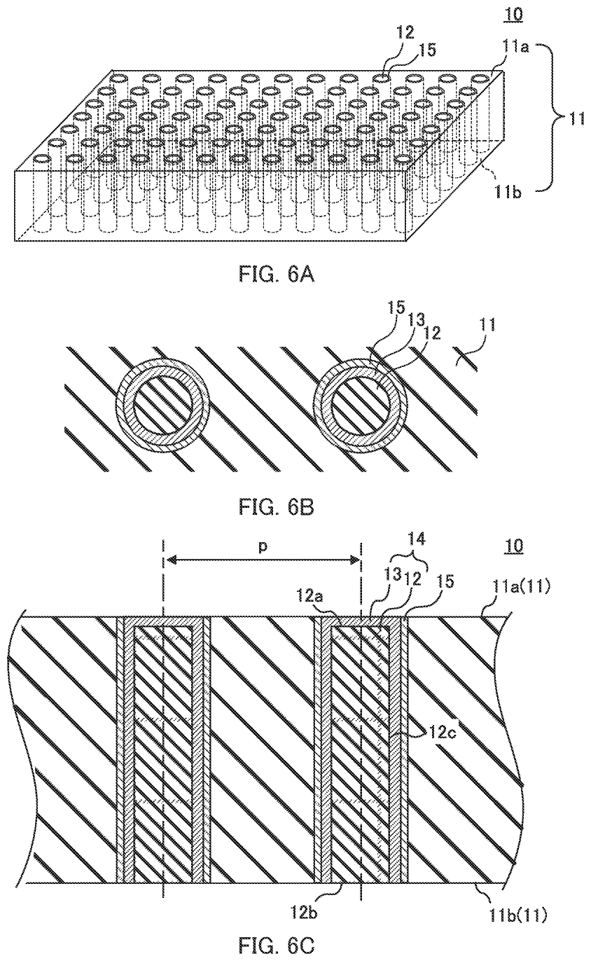

FIG. 6A is a perspective view illustrating anisotropic conductive sheet 10 according to Embodiment 2, FIG. 6B is a partially enlarged view of anisotropic conductive sheet 10 illustrated in FIG. 6A taken along a horizontal cross-section (a partial sectional view taken along a direction orthogonal to the thickness direction), and FIG. 6C is a partially enlarged view of anisotropic conductive sheet 10 illustrated in FIG. 6A taken along a vertical cross-section (a partial sectional view taken along a thickness direction).

As illustrated in FIGS. 6A to 6C, anisotropic conductive sheet 10 includes insulation layer 11, a plurality of conductive paths 14 extending in the thickness direction inside the insulation layer 11, and a plurality of bonding layers 15 disposed at least at a part between the plurality of conductive paths 14 and insulation layer 11.

Conductive path 14 includes columnar resin 12, and conductive layer 13 disposed at least at a part between columnar resin 12 and insulation layer 11. Bonding layer 15 is disposed between conductive layer 13 and insulation layer 11.

Specifically, anisotropic conductive sheet 10 according to the present embodiment has the same configuration as that of anisotropic conductive sheet 10 according to Embodiment 1 except that the plurality of bonding layers 15 is further provided at least at a part between the plurality of conductive layers 13 and insulation layer 11. In view of this, the same member and composition as those of Embodiment 1 are denoted with the same reference numerals or names, and the description thereof will be omitted.

### 1-1. Bonding Layer 15

Bonding layer 15 is disposed at least at a part between conductive layer 13 and insulation layer 11. In addition, bonding layer 15 increases the adhesiveness between conductive layer 13 and insulation layer 11 such that peeling less occurs at the boundary surface. That is, bonding layer 15 may function also as a bonding or primer layer that enhances the adhesiveness between conductive layer 13 and insulation layer 11.

Bonding layer 15 is disposed at least a part of the surface of conductive layer 13 (see FIG. 6C). In the present embodiment, it is disposed to surround the surface of conductive layer 13.

The material of bonding layer 15 is not limited as long as sufficient bonding between columnar resin 12 and insulation layer 11 can be ensured. The material of bonding layer 15 may be an organic-inorganic composite composition containing a polycondensation products of alkoxysilane or its oligomers, or may be a third resin composition.

### Organic-Inorganic Composite Composition

The organic-inorganic composite composition contains a polycondensation products of alkoxysilane or its oligomers.

Alkoxysilane is an alkoxysilane compound in which two to four alkoxy groups are bonded to silicon. That is, an alkoxysilane can be a bifunctional alkoxysilane, a trifunctional alkoxysilane, a tetrafunctional alkoxysilane, or a mixture of one or more of these. Among them, from the viewpoint of forming three-dimensional cross-links and facilitating sufficient adhesion, it is preferable that the alkoxysilane contains a trifunctional or tetrafunctional alkoxysilane, and it is more preferable that it contains a tetrafunctional alkoxysilane (tetraalkoxysilane). Oligomers of alkoxysilanes can be partially hydrolyzed and polycondensed alkoxysilanes.

Specifically, it is preferable that the alkoxysilane or its oligomer include, for example, the compound shown in Formula 1 below.

RSiO—(Si(OR)2O)n-SiR (Formula 1)

In Formula 1, R is independently an alkyl group, and n is an integer from 0 to 20. Examples of alkoxysilane represented by Formula 1 include tetramethoxysilane, tetraethoxysilane, and tetrabutoxysilane.

The alkoxysilane or its oligomer may be commercially available. Examples of commercially available oligomers of alkoxysilane include Colcoat N-103X and Colcoat PX manufactured by Colcoat.

The organic-inorganic composite composition may further contain other components, such as conductive materials, silane coupling agents, and surfactants as necessary.

### Third Resin Composition

From the viewpoint of suppressing cracking of conductive layer 13 due to the first resin composition (the cross-linked product of the first elastomer composition) constituting insulation layer 11 that is expanded under heating, from the viewpoint of suppressing the contact of conductive layer 13 breaking through bonding layer 15 with the adjacent conductive layer 13 (suppressing short circuit), and from other similar viewpoints, it is preferable that the glass transition temperature of the third resin composition constituting bonding layer 15 be, but not limited thereto, higher than the glass transition temperature of the first resin composition constituting insulation layer 11. In addition, from the viewpoint of highly suppressing the cracking and short circuit of conductive layer 13, it is preferable that the glass transition temperature of the third resin composition constituting bonding layer 15 be the same as or higher than the glass transition temperature of the second resin composition preferable, while the glass transition temperature of the third resin composition constituting bonding layer 15 may be the same as, or different from the glass transition temperature of the second resin composition constituting columnar resin 12.

More specifically, preferably, the glass transition temperature of the third resin composition is 150° C. or above, more preferably 160 to 600° C. The glass transition temperature of the third resin composition can be measured by the same method as that described above.

From the viewpoint of easily meeting the above-mentioned glass transition temperature while providing adhesiveness, it is preferable that the third resin composition constituting bonding layer 15 be the same as the second resin composition constituting columnar resin 12, while the third resin composition constituting bonding layer 15 is not limited. Specifically, the third resin composition may be a cross-linked product of a composition containing an elastomer and a crosslinking agent (hereinafter also referred to as “third elastomer composition”), or a resin composition containing a resin that is not an elastomer or a cured product of a resin composition containing a curable resin that is not an elastomer and a curing agent.

The elastomer contained in the third elastomer composition to be used may be the same as the above-described examples of the elastomer contained in the first elastomer composition. The type of the elastomer contained in the third elastomer composition may be the same as, or different from the type of the elastomer contained in the first elastomer composition. For example, from the viewpoint of easily increasing the affinity and adhesion between insulation layer 11 and bonding layer 15, the type of the elastomer contained in the third elastomer composition may be the same as the type of the elastomer contained in the first elastomer composition.

From the viewpoint of easily meeting the above-mentioned glass transition temperature, the weight average molecular weight of the elastomer contained in the third elastomer composition be, but not limited thereto, higher than the weight average molecular weight of the elastomer contained in the first elastomer composition. The weight average molecular weight of the elastomer can be measured in polystyrene equivalent by gel permeation chromatography (GPC).

The crosslinking agent contained in the third elastomer composition may be appropriately selected in accordance with the type of the elastomer, and the crosslinking agent contained in the third elastomer composition to be used may be the same as the above-described examples of the crosslinking agent contained in the first elastomer composition. From the viewpoint of easily meeting the above-mentioned glass transition temperature, it is preferable that the content of the crosslinking agent in the third elastomer composition be, but not limited thereto, larger than the content of the crosslinking agent in the first elastomer composition. In addition, it is preferable that the degree of crosslinking (gel fraction) of the cross-linked product of the third elastomer composition be higher than the degree of crosslinking (gel fraction) of the cross-linked product of the first elastomer composition.

The resin (including a curable resin) that is not an elastomer and the curing agent contained in the third resin composition to be used may be the same as the above-described examples of the resin that is not an elastomer and curing agent contained in the second resin composition. Preferably, the resin that is not an elastomer contained in the third resin composition is polyimide, polyamide imide, acrylic resin, or epoxy resin.

Among them, preferably, the third resin composition is a resin composition containing a resin that is not an elastomer or a cured product of a resin composition containing a curable resin that is not an elastomer and curing agent from the viewpoint of suppressing the above-described cracking of conductive layer 13 and short circuit of conductive layers 13 by making it easier to meet the above-mentioned glass transition temperature.

### Thickness

The thickness of bonding layer 15 is not limited as long as conductive layer 13 and insulation layer 11 can be sufficiently bonded without impairing the function of conductive layer 13. Normally, it is preferable that the thickness of bonding layer 15 be smaller than the thickness of conductive layer 13. Preferably, the thickness of bonding layer 15 is 1 μm or smaller, more preferably 0.5 μm or smaller.

### 2. Manufacturing Method of Anisotropic Conductive Sheet

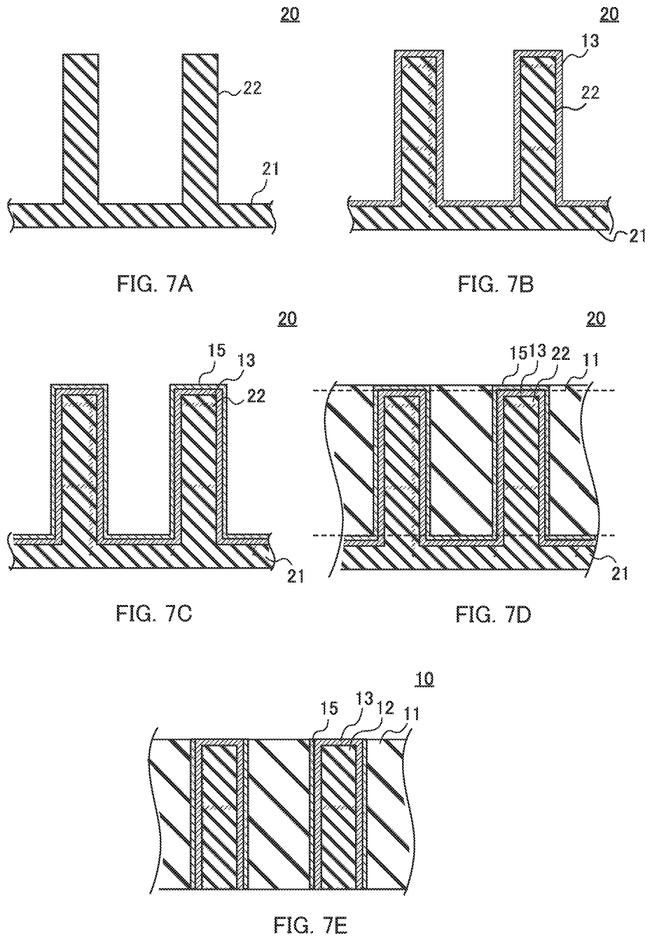

FIGS. 7A to 7E are partial sectional views illustrating a manufacturing process of anisotropic conductive sheet 10 according to the present embodiment.

As illustrated in FIGS. 7A to 7E, anisotropic conductive sheet 10 according to the present embodiment is obtained through 1) a step of preparing base material 20 including supporting part 21 and the plurality of column parts 22 disposed on its one surface, and composed of the second resin composition or its precursor resin (see FIG. 7A), 2) a step of forming conductive layer 13 on the surface of column part 22 (see FIG. 7B), 3) a step of forming bonding layer 15 on the surface of conductive layer 13 (see FIG. 7C), 4) a step of forming insulation layer 11 in the space between the plurality of column parts 22 (see FIG. 7D), and 5) a step of obtaining anisotropic conductive sheet 10 by removing supporting part 21 of resin base material 20 and unnecessary parts such as excess bonding layer 15 (the portion outside the broken line in FIG. 7D) (see FIG. 7E).

That is, except for a step of forming bonding layer 15 on the surface of conductive layer 13 between step 2) (the step of forming conductive layer 13) and step 3) (the step of forming insulation layer 11) in Embodiment 1, the manufacturing method may be the same as the manufacturing method of anisotropic conductive sheet 10 according to Embodiment 1.

Steps 1), 2), 4) and 5) of the present embodiment are the same as steps 1), 2), 3) and 4) of Embodiment 1, respectively.

### Step 3)

Next, bonding layer 15 is formed on the surface of conductive layer 13 (see FIG. 7C).

More specifically, column part 22 on which conductive layer 13 is formed is immersed in the above-described solution containing alkoxysilane or its oligomer or the third resin composition or its precursor (such as a resin composition containing epoxy resin and curing agent, and the third elastomer composition), or the solution or composition is applied on the surface of column part 22 on which conductive layer 13 is formed, for example.

Next, the applied solution containing alkoxysilane or its oligomer (or the third resin composition or its precursor) is dried or heated to cause polycondensation of the alkoxysilane or its oligomer (or dry or crosslink the third resin composition or its precursor). In this manner, bonding layer 15 containing a polycondensation product of alkoxysilane or its oligomer (or bonding layer 15 composed of the third resin composition) is formed.

The drying or heating may be performed in such a manner as to cause polycondensation of alkoxysilane or its oligomer in the solution (or dry or crosslink the third resin composition or its precursor). For example, in the case where polycondensation of the solution containing alkoxysilane or its oligomer is caused, preferably, the dry temperature may be 80° C. or above, more preferably 120° C. or above. The duration of the drying may be, for example, 1 to 10 minutes although it depends on the dry temperature.

Anisotropic conductive sheet 10 according to the present embodiment may be used for an electrical testing apparatus and an electrical testing method as in Embodiment 1. The details of the electrical testing apparatus and the electrical testing method are the same as those of Embodiment 1.

Operation

Anisotropic conductive sheet 10 according to the present embodiment includes bonding layer 15 disposed between the plurality of conductive layers 13 and insulation layer 11. Thus, the following effects are further achieved while achieving the effects described in Embodiment 1.

Specifically, even when pressurization and depressurization are repeated in electrical testing, the peeling less occurs at the boundary surface between insulation layer 11 and conductive layer 13 of anisotropic conductive sheet 10 because the adhesiveness between the plurality of conductive layers 13 and insulation layer 11 is increased. In this manner, precise electrical testing can be performed.

In particular, in the case where the storage modulus (G2) of the second resin composition constituting columnar resin 12 at 25° C. is higher than the storage modulus (G1) of the first resin composition constituting insulation layer 11 at 25° C., or more specifically, in the case where G1/G2 is smaller than 1, preferably 0.1 or smaller, peeling tends to occur at the boundary surface between conductive path 14 and insulation layer 11 due to the repeated pressurization and depressurization. In such a case, the provision of bonding layer 15 is especially effective.

### 3. Modification

Note that while anisotropic conductive sheet 10 illustrated in FIGS. 6B and 6C is described in the present embodiment, this is not limitative. For example, in the case where the second resin composition constituting columnar resin 12 has conductivity, end surface 12a of columnar resin 12 may be exposed to first surface 11a side, and end surface 12b may be exposed to second surface 11b side.

In addition, anisotropic conductive sheet 10 according to the present embodiment may further include layers other than the above-mentioned layers as necessary. For example, an electrolyte layer (not illustrated in the drawing) may be further disposed on conductive layer 13 disposed at end surface 12a of columnar resin 12 (conductive layer 13 exposed to first surface 11a side).

Electrolyte layer is, for example, a coating containing a lubricant. Thus, when the inspection object is disposed on first surface 11a, deformation of the terminal of the inspection object and adhesion of the electrode material of the inspection object to conductive layer 13 can be suppressed without impairing the electrical connection with the terminal of the inspection object. It is preferable that the lubricant contained in the electrolyte layer be alkyl sulfonate metal salt from the viewpoint of having less negative influences such as contamination of the electrode of the inspection object, especially from the viewpoint of having less negative influences during use at high temperature. The electrolyte layer may be disposed over the entire surface of anisotropic conductive sheet 10 on first surface 11a side.

In addition, in the present embodiment, in the manufacturing method of anisotropic conductive sheet 10, bonding layer 15 is formed by drying or crosslinking the third resin composition or its precursor in step 3), and then insulation layer 11 is formed by crosslinking the first elastomer composition (the precursor of the first resin composition) in step 4), but this is not limitative. For example, bonding layer 15 and insulation layer 11 may be simultaneously formed by performing the drying or crosslinking of the third resin composition or its precursor of step 3) simultaneously with the crosslinking of the first elastomer composition of step 4).

In addition, also in the present embodiment, deformation may be performed as in the modification of Embodiment 1 (see FIGS. 4A to 5B).

### Embodiment 3

### 1. Anisotropic Conductive Sheet

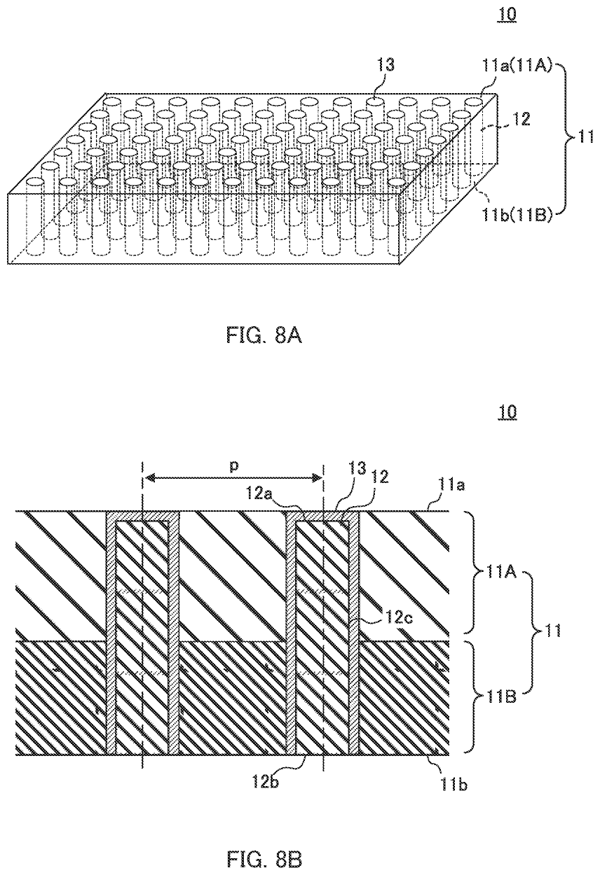

FIG. 8A is a perspective view illustrating anisotropic conductive sheet 10 according to Embodiment 3, and FIG. 8B is a partially enlarged view of anisotropic conductive sheet 10 illustrated in FIG. 8A taken along a vertical cross-section (a partial sectional view taken along a thickness direction).

As illustrated in FIGS. 8A and 8B, anisotropic conductive sheet 10 includes insulation layer 11, the plurality of columnar resins 12 extending in the thickness direction inside the insulation layer 11, and the plurality of conductive layers 13 disposed between the plurality of columnar resins 12 and insulation layer 11. Insulation layer 11 includes first insulation layer 11A and second insulation layer 11B.

That is, the same configuration as that of anisotropic conductive sheet 10 according to Embodiment 1 is provided except that insulation layer 11 of Embodiment 1 is replaced by insulation layer 11 including first insulation layer 11A and second insulation layer 11B. In view of this, the same member and composition as those of Embodiment 1 are denoted with the same reference numerals or names, and the description thereof will be omitted.

### 1-1. Insulation Layer 11

Insulation layer 11 includes first insulation layer 11A and second insulation layer 11B (see FIG. 8B).

### First Insulation Layer 11A

First insulation layer 11A may function as a support layer (or a base material layer) of insulation layer 11. First insulation layer 11A includes first surface 11a, and is composed of the first resin composition.

Since first insulation layer 11A includes first surface 11a on which to dispose the inspection object, it is preferable that it does not have an adhesive property. More specifically, preferably, the probe tack value at first surface 11a of first insulation layer 11A at 25° C. is 1N/5 mmφ or smaller. The probe tack value can be measured at 25° C. in accordance with ASTM D2979:2016.

Likewise, preferably, the specific adhesive force to the SUS surface of first insulation layer 11A at 25° C. is 1N/25 mm or smaller. The adhesive force can be measured as an adhesive force at a peel-off angle of 90° in accordance with JIS 0237:2009.

The first resin composition constituting first insulation layer 11A is not limited as long as the probe tack value or the adhesive force meets the above-mentioned range and it can insulate between the plurality of conductive layers 13. Preferably, the storage modulus or glass transition temperature of the first resin composition constituting first insulation layer 11A is the same as or lower than the storage modulus or glass transition temperature of the second resin composition constituting columnar resin 12 from the viewpoint of suppressing damages on the terminal of the inspection object. In addition, from the viewpoint of easily ensuring the strength of insulation layer 11 while the probe tack value or adhesive force of first insulation layer 11A meets the above-mentioned range, it is preferable that the storage modulus or glass transition temperature of the first resin composition constituting first insulation layer 11A be higher than the storage modulus or glass transition temperature of the fourth resin composition constituting second insulation layer 11B.

Specifically, the range of the storage modulus (G1) and glass transition temperature of the first resin composition constituting first insulation layer 11A at 25° C. may be the same as the range of the storage modulus (G1) and glass transition temperature of the first resin composition at 25° C. of Embodiment 1.

The probe tack value, adhesive force, storage modulus and glass transition temperature of the first resin composition may be adjusted by the type and degree of crosslinking (or gel fraction) of the elastomer described later, the amount of filler added and the like. In addition, the storage modulus of the first resin composition may also be adjusted by the form of the resin composition (e.g., whether it is porous or not).

The first resin composition constituting first insulation layer 11A is not limited as long as it has an insulation property and meets the above-mentioned physical property, but may be the first resin composition of Embodiment 1, i.e., the first elastomer composition.

Thickness T1 of first insulation layer 11A is set such that, but not limited thereto, the ratio (T1/T2) of thickness T1 of first insulation layer 11A and thickness T2 of second insulation layer 11B is 1/9 to 9/1, preferably 4/6 to 9/1, for example. When thickness T1 of first insulation layer 11A has a predetermined value or greater, the shape of insulation layer 11 can be easily favorably maintained, and when thickness T1 of first insulation layer 11A has a predetermined value or smaller, thickness T2 of second insulation layer 11B is not excessively reduced and thus the adhesive property of second surface 11b are less impaired. More specifically, preferably, thickness T1 of first insulation layer 11A is 2 to 90 μm, more preferably 20 to 80 μm.

### Second Insulation Layer 11B

Second insulation layer 11B is stacked on first insulation layer 11A, and functions as an adhesive layer. Second insulation layer 11B includes second surface 11b, and is composed of the fourth resin composition.

As described above, second insulation layer 11B functions as an adhesive layer and as such has an adhesive property. That is, preferably, the probe tack value of second surface 11b of second insulation layer 11B at 25° C. is higher than the probe tack value at first surface 11a of first insulation layer 11A at 25° C. More specifically, preferably, the probe tack value of second insulation layer 11B at 25° C. is 3N/5 mmφ or greater. When the probe tack value of second insulation layer 11B at 25° C. is 3N/5 mmφ or greater, a sufficient adhesive property can be achieved, and mounting and fixing to the measurement apparatus can be readily performed by only placing anisotropic conductive sheet 10 even without using special jigs and the like. From the above-described viewpoint, preferably, the probe tack value of second insulation layer 11B at 25° C. is 5 to 50N/5 mmφ, still more preferably 7 to 50N/5 mmφ. The probe tack value can be measured by the same method as that described above.

Preferably, the adhesive force to the SUS surface of second insulation layer 11B at 25° C. is higher than the adhesive force to the SUS surface of first insulation layer 11A at 25° C. More specifically, preferably, the adhesive force to the SUS surface of second insulation layer 11B at 25° C. is 0.8 to 10N/25 mm, more preferably 5 to 10N/25 mm. The adhesive force can be measured by the same method as that described above.

From the viewpoint of easily achieving the probe tack value and adhesive force meeting the above-mentioned range, it is preferable that the storage modulus (G4) of the fourth resin composition constituting second insulation layer 11B at 25° C. be lower than the storage modulus (G1) of the first resin composition constituting first insulation layer 11A at 25° C. More specifically, it is preferable that the ratio G4/G1 of the storage modulus (G4) of the fourth resin composition and the storage modulus (G1) of the first resin composition be 0.001 to 0.9. The storage modulus G4 of the fourth resin composition is not limited as long as the above-mentioned relationship is met, but is preferably 1.0×10⁴ to 1.0×10⁶ Pa, for example. The storage modulus G4 of the fourth resin composition can be measured by the same method as that described above.

Preferably, the glass transition temperature of the fourth resin composition constituting second insulation layer 11B is lower than the glass transition temperature of the first resin composition constituting first insulation layer 11A from the viewpoint of easily achieving the probe tack value and adhesive force meeting the above-mentioned range. More specifically, preferably, the glass transition temperature of the fourth resin composition is −40° C. or below. The glass transition temperature of the fourth resin composition can be measured by the same method as that described above.

The tack value, adhesive force, storage modulus, and glass transition temperature of the fourth resin composition probe may be adjusted by the type and weight average molecular weight of the elastomer, the degree of crosslinking (or gel fraction) described later and the like.

From the viewpoint of easily achieving the probe tack value, adhesive force, storage modulus, and glass transition temperature meeting the above-mentioned relationship, it is preferable that the fourth resin composition be a cross-linked product of a composition (hereinafter also referred to as “fourth elastomer composition”) containing an elastomer (base polymer) and a crosslinking agent as with the first resin composition.

The elastomer contained in the fourth elastomer composition to be used may be the same as the above-described examples of the elastomer contained in the first elastomer composition. The type of the elastomer contained in the fourth elastomer composition may be the same as, or different from the type of the elastomer contained in the first elastomer composition. From the viewpoint of easily increasing the adhesion between first insulation layer 11A and second insulation layer 11B, it is preferable that the type of the elastomer contained in the fourth elastomer composition be the same as the type of the elastomer contained in the first elastomer composition. For example, since the elastomer contained in the first elastomer composition is preferably silicone rubber, the elastomer contained in the fourth elastomer composition is also preferably silicone rubber.

From the viewpoint of easily achieving the probe tack value, adhesive force, storage modulus, and glass transition temperature meeting the above-mentioned relationship, the weight average molecular weight of the elastomer contained in the fourth elastomer composition may be lower than the weight average molecular weight of the elastomer contained in the first elastomer composition, for example, while the weight average molecular weight of the elastomer contained in the fourth elastomer composition is not limited. The weight average molecular weight of the elastomer may be measured in polystyrene equivalent by gel permeation chromatography (GPC).

The crosslinking agent contained in the fourth elastomer composition may be appropriately selected in accordance with the type of the elastomer. The crosslinking agent contained in the fourth elastomer composition to be used may be the same as the above-described examples of the crosslinking agent contained in the first elastomer composition. While the content of the crosslinking agent in the fourth elastomer composition is not limited, it is preferable that the content of the crosslinking agent in the fourth elastomer composition be smaller than the content of the crosslinking agent in the first elastomer composition from the viewpoint of easily achieving the probe tack value, adhesive force, storage modulus or glass transition temperature meeting the above-mentioned relationship.

As described above, the fourth elastomer composition may further include other components such as adhesion-imparting agents, silane coupling agents, and fillers as necessary.

From the viewpoint of easily achieving the probe tack value, adhesive force, storage modulus, and glass transition temperature meeting the above-mentioned relationship, it is preferable that the degree of crosslinking of the cross-linked product of the fourth elastomer composition constituting second insulation layer 11B be lower than the degree of crosslinking of the cross-linked product of the first elastomer composition constituting first insulation layer 11A. That is, it is preferable that the gel fraction of the cross-linked product of the fourth elastomer composition constituting second insulation layer 11B be lower than the gel fraction of the cross-linked product of the first elastomer composition constituting first insulation layer 11A.

Preferably, the peel strength (interlayer peel strength) between second insulation layer 11B and first insulation layer 11A at 25° C. is 5N/25 mm or greater, more preferably 7 to 30N/25 mm. The peel strength (interlayer peel strength) can be measured by a 180° peel test in accordance with ISO 29862:2007 (JIS Z 0237:2009) at 25° C. and a peel speed of 300 mm/min.

Preferably, thickness T2 of second insulation layer 11B is set such that the thickness ratio (T1/T2) falls within the above-mentioned range.

### 1-2. Columnar Resin 12

It suffices that the second resin composition constituting columnar resin 12 can stably support conductive layer 13, and may or may not be the same as the first resin composition constituting first insulation layer 11A. Even in the case where the second resin composition constituting columnar resin 12 and the first resin composition constituting first insulation layer 11A are the same, columnar resin 12 and first insulation layer 11A can be discriminated from each other by, for example, confirming the boundary line between columnar resin 12 and insulation layer 11 and the like in the cross-section of anisotropic conductive sheet 10. In particular, preferably, the storage modulus or glass transition temperature of the second resin composition constituting columnar resin 12 is the same as or higher than the storage modulus or glass transition temperature of the first resin composition constituting first insulation layer 11A from the viewpoint of easily and stably support conductive layer 13.

That is, preferably, the storage modulus (G2) of the second resin composition at 25° C. is 1.0×10⁶ to 1.0×10¹⁰ Pa, more preferably 1.0×10⁸ to 1.0×10¹⁰ Pa. The storage modulus of the second resin composition can be measured by the same method as that described above.

In addition, the ratio G2/(G1+G4) of the storage modulus (G2) of the second resin composition and the sum (G1+G4) of the storage modulus (G1) of the first resin composition and the storage modulus (G4) of the fourth resin composition is preferably 9.0 to 9.0×10⁴ in the case where the thickness ratio (T1/T2) of first insulation layer 11A and second insulation layer 11B is 4/6 to 9/1, for example. When G2/(G1+G4) is 9.0 or greater, columnar resin 12 has a suitable strength, and it is easy to stably hold conductive layer 13. When G2/(G1+G4) is 9.0×10⁴ or smaller, the strength of the entire insulation layer 11 is not excessively low, and it is easy to suppress cracking and the like of conductive layer 13 due to expansion and deformation of insulation layer 11 under heating.

From the same viewpoint, it is preferable that G2/G1 be 10.0 to 1.0×10⁵, and that G2/G4 be 1.0×10² to 1.0×10⁶. When G2/G1 (or G2/G4) is the lower limit value or greater, columnar resin 12 has a suitable strength, and it is easy to stably hold conductive layer 13. When G2/G1 (or G2/G4) is the upper limit or smaller, the strength of first insulation layer 11A (or second insulation layer 11B) is not excessively low, and it is easy to suppress cracking and the like of conductive layer 13 due to expansion and deformation of first insulation layer 11A (or second insulation layer 11B) under heating.

### 2. Manufacturing Method of Anisotropic Conductive Sheet

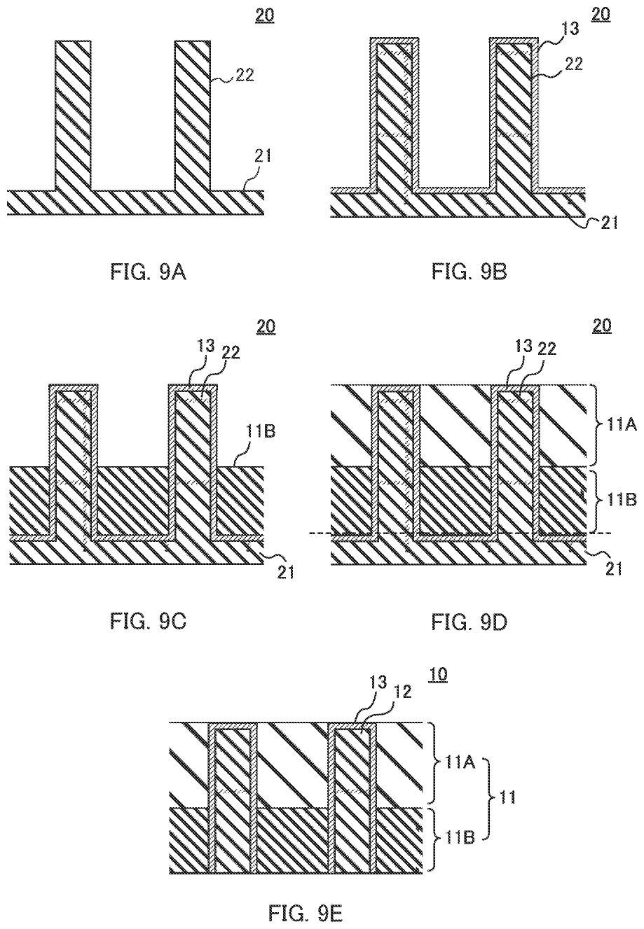

FIGS. 9A to 9E are partial sectional views illustrating a manufacturing process of anisotropic conductive sheet 10 according to the present embodiment.

As illustrated in FIGS. 9A to 9E, anisotropic conductive sheet 10 according to the present embodiment is obtained through 1) a step of preparing base material 20 including supporting part 21 and the plurality of column parts 22 disposed on its one surface, and composed of the second resin composition or its precursor resin (see FIG. 9A), 2) a step of forming conductive layer 13 on the surface of column part 22 (see FIG. 9B), 3) a step of forming second insulation layer 11B in the space between the plurality of column parts 22 (see FIG. 9C), 4) a step of forming first insulation layer 11A on the second insulation layer 11B (see FIG. 9D), and 5) a step of removing supporting part 21 of resin base material 20 (see FIG. 9E).

That is, the manufacturing method may be the same as the manufacturing method of anisotropic conductive sheet 10 according to Embodiment 1 except that 3) a step of forming second insulation layer 11B (see FIG. 9C) and 4) a step of forming first insulation layer 11A on the second insulation layer 11B (see FIG. 9D) are performed in place of step 3) (the step of forming insulation layer 11 by supplying with first resin composition R1) of Embodiment 1.

Steps 1), 2) and 5) of the present embodiment are the same as steps 1), 2) and 4) of Embodiment 1, respectively.

### Step 3)

Second insulation layer 11B is supplied in the space between the plurality of column parts 22 (see FIG. 9C).

More specifically, the fourth elastomer composition (the precursor of the fourth resin composition) for obtaining second insulation layer 11B is supplied in the space between the plurality of column parts 22. The fourth elastomer composition can be supplied by any methods such as a dispenser.

Next, the fourth elastomer composition is dried or heated to crosslink the elastomer composition. In this manner, second insulation layer 11B composed of the cross-linked product of the fourth elastomer composition (the fourth resin composition) is formed.

The drying or heating may be performed in such a manner as to crosslink the fourth elastomer composition. The drying or heating temperature may be preferably 100 to 170° C. The duration of the drying or heating may be, for example, 5 to for 60 minutes although it depends on the drying or heating temperature.

### Step 4)

First insulation layer 11A is formed on second insulation layer 11B in the space between the plurality of column parts 22 (see FIG. 9D).

More specifically, the first elastomer composition (a precursor of the first resin composition) for obtaining first insulation layer 11A is supplied to the space between the plurality of column parts 22 (see FIG. 9D). The first elastomer composition may be supplied by the same method as that described above.

Next, as described above, the supplied first elastomer composition is dried or heated to crosslink the elastomer composition. In this manner, first insulation layer 11A composed of the cross-linked product of the first elastomer composition (the first resin composition) is formed.

The drying or heating may be performed under the same condition as that of the drying or heating of step 3).

Anisotropic conductive sheet 10 according to the present embodiment may be used for an electrical testing apparatus and an electrical testing method as in Embodiment 1. The details of the electrical testing apparatus and the electrical testing method are the same as those of Embodiment 1.

### Operation

Anisotropic conductive sheet 10 according to the present embodiment includes second insulation layer 11B. Thus, the following effects are further achieved while achieving the effects described in Embodiment 1.

Specifically, mounting and fixing to the apparatus can be performed by only putting anisotropic conductive sheet 10 on inspection substrate 120 of electrical testing apparatus 100. Thus, unlike in the related art, it is not necessary to use a fixation jig for mounting and fixing the anisotropic conductive sheet to the measurement apparatus, and mounting and fixing to the apparatus do not take much time.

### 3. Modification

Note that while anisotropic conductive sheet 10 illustrated in FIG. 8B is described in the present embodiment, this is not limitative. For example, anisotropic conductive sheet 10 may further include layers other than the above-mentioned layers as necessary. Example of the other layers include a bonding layer and an electrolyte layer.

### Bonding Layer

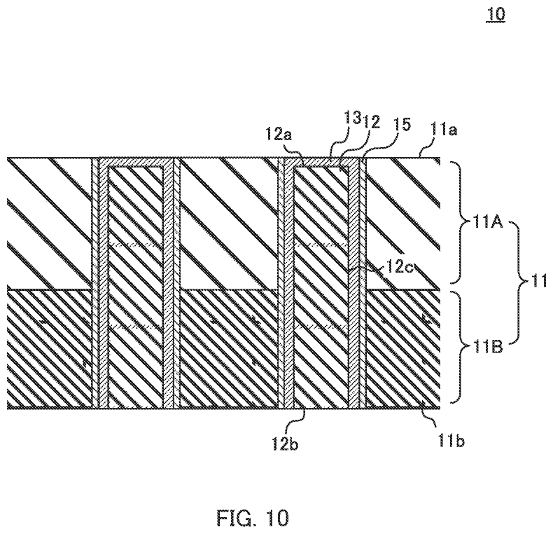

FIG. 10 is a partial sectional view illustrating anisotropic conductive sheet 10 according to a modification.

As illustrated in FIG. 10, anisotropic conductive sheet 10 may further include the plurality of bonding layers 15 disposed at least at a part between the plurality of conductive layers 13 and insulation layer 11.

The material of bonding layer 15 may be the same material as that of columnar resin 12. That is, bonding layer 15 may be composed of a cross-linked product of an elastomer composition containing an elastomer and a crosslinking agent; or may be composed of a resin composition containing a resin that is not an elastomer, or a cured product of a resin composition containing a curable resin that is not an elastomer and a curing agent.

The elastomer and the crosslinking agent to be used may be the same as the above-described examples of the elastomer and crosslinking agent in the above-described second elastomer composition. In addition, the resin that is not an elastomer and curing agent to be used may be the same as the above-described examples of the resin that is not an elastomer and curing agent in the second resin composition. Alternatively, bonding layer 15 may be a layer containing a polycondensation product of alkoxysilane or its oligomer. The alkoxysilane or its oligomer may be commercially available products, such as Colcoat N-103X and Colcoat PX manufactured by Colcoat, for example. Alternatively, bonding layer 15 and its material may be the same as the bonding layer and its material of Embodiment 2.

### Transition Layer

In addition, anisotropic conductive sheet 10 may further include a transition layer (not illustrated in the drawing) disposed between first insulation layer 11A and second insulation layer 11B.

The transition layer may be a cross-linked product of an elastomer composition containing an elastomer and a crosslinking agent as with first insulation layer 11A and second insulation layer 11B, for example. Then, the degree of crosslinking (gel fraction) of the cross-linked product of the elastomer composition constituting the transition layer may be lower than the degree of crosslinking (gel fraction) of the cross-linked product of the first elastomer composition constituting first insulation layer 11A, and higher than the degree of crosslinking (gel fraction) of the cross-linked product of the fourth elastomer composition constituting second insulation layer 11B. When such a transition layer is further provided, the adhesion between first insulation layer 11A and second insulation layer 11B can be further increased.

### Electrolyte Layer

In addition, an electrolyte layer (not illustrated in the drawing) may be further disposed on conductive layer 13 disposed at end surface 12a of columnar resin 12 (conductive layer 13 exposed to first surface 11a side).

The electrolyte layer is, for example, a coating containing a lubricant. Thus, when the inspection object is disposed on first surface 11a, deformation of the terminal of the inspection object and adhesion of the electrode material of the inspection object to conductive layer 13 can be suppressed without impairing the electrical connection with the terminal of the inspection object. It is preferable that the lubricant contained in the electrolyte layer be alkyl sulfonate metal salt from the viewpoint of having less negative influences such as contamination of the electrode of the inspection object, especially from the viewpoint of having less negative influences during use at high temperature. The electrolyte layer may be disposed over the entire surface of anisotropic conductive sheet 10 on first surface 11a side.

In addition, while conductive layer 13 is disposed on end surface 12a of columnar resin 12 in the present embodiment, this is not limitative, and may be further disposed on end surface 12b.

Alternatively, in the case where the second resin composition constituting columnar resin 12 has conductivity, conductive layer 13 may not be disposed on end surfaces 12a and 12b of columnar resin 12. That is, end surface 12a of columnar resin 12 may be exposed to first surface 11a side, and end surface 12b may be exposed to second surface 11b side.

In addition, in the manufacturing method of anisotropic conductive sheet 10, second insulation layer 11B is formed by crosslinking the fourth elastomer composition (the precursor of the fourth resin composition) at step 3) and then first insulation layer 11A is formed by crosslinking the first elastomer composition (the precursor of the first resin composition) at step 4) in the present embodiment, but this is not limitative. For example, second insulation layer 11B and first insulation layer 11A may be simultaneously formed by performing the crosslinking of the fourth elastomer composition at step 3) simultaneously with the crosslinking of the first elastomer composition at step 4).

In addition, second insulation layer 11B may be formed at step 4) after first insulation layer 11A is formed at step 3). In this manner, at step 5), first insulation layer 11A with low adhesive can be cut, and favorable handleability can be achieved. Naturally, the crosslinking of the fourth elastomer composition at step 3) and the crosslinking of the first elastomer composition at step 4) may be simultaneously performed.

In addition, also in the present embodiment, deformation may be performed as in the modification of Embodiment 1 (see FIGS. 4A to 5B).

This application is entitled to and claims the benefit of Japanese Patent Application No. 2019-036179 filed on February 28, Japanese Patent Application No. 2019-98814 filed on May 27, and Japanese Patent Application No. 2019-98816 filed on May 27, the disclosures each of which including the specification, drawings and abstract is incorporated herein by reference in its entirety.

### INDUSTRIAL APPLICABILITY

According to the present disclosure, an anisotropic conductive sheet, an electrical testing apparatus and an electrical testing method that can suppress damage of inspection objects can be provided.

### REFERENCE SIGNS LIST

10 Anisotropic conductive sheet
11 Insulation layer
11a First surface
11b Second surface
11A First insulation layer
11B Second insulation layer
12 Columnar resin
12a, 12b End surface
12c Side surface
13 Conductive layer
14 Conductive path
15 Bonding layer
20 Resin base material
21 Supporting part
22 Column part
100 Electrical testing apparatus
110 Holding container
120 Inspection substrate
121 Electrode
130 Inspection object
131 Terminal (of inspection object)

1. An anisotropic conductive sheet, comprising:
an insulation layer including a first surface and a second surface, and comprising a first resin composition;
a plurality of columnar resins disposed to extend in a thickness direction in the insulation layer, and comprising a second resin composition; and
a plurality of conductive layers disposed between the plurality of columnar resins and the insulation layer, and exposed to outside of the first surface and the second surface.

2. The anisotropic conductive sheet according to claim 1, wherein each of the plurality of conductive layers is disposed to surround a side surface of each of the plurality of columnar resins.

3. The anisotropic conductive sheet according to claim 1, wherein each of the plurality of conductive layers is further disposed on an end surface of each of the plurality of columnar resins on a first surface side.

4. The anisotropic conductive sheet according to claim 3, wherein each of the plurality of conductive layers is further disposed on an end surface of each of the plurality of columnar resins on a second surface side.

5. The anisotropic conductive sheet according to claim 3, further comprising an electrolyte layer disposed on each of the plurality of conductive layers on the end surface on the first surface side.

6. The anisotropic conductive sheet according to claim 5, wherein the electrolyte layer includes a lubricant.

7. The anisotropic conductive sheet according to claim 6, wherein the lubricant includes alkyl sulfonate metal salt.

8. The anisotropic conductive sheet according to claim 1, wherein a glass transition temperature of the second resin composition is 120° C. or above.

9. The anisotropic conductive sheet according to claim 1, wherein a storage modulus of the second resin composition at 25° C. is 1.0×10⁶ to 1.0×10¹⁰ Pa.

10. The anisotropic conductive sheet according to claim 9, wherein the storage modulus of the second resin composition at 25° C. is 1.0×10⁸ to 1.0×10¹⁰ Pa.

11. The anisotropic conductive sheet according to claim 1, wherein a storage modulus of the first resin composition at 25° C. is lower than a storage modulus of the second resin composition at 25° C.

12. The anisotropic conductive sheet according to claim 1, wherein the second resin composition is a conductive resin composition.

13. The anisotropic conductive sheet according to claim 1, further comprising a plurality of bonding layers, each of which is disposed at least at a part between the plurality of conductive layers and the insulation layer.

14. The anisotropic conductive sheet according to claim 13, wherein a thickness of the bonding layer is smaller than a thickness of each of the plurality of conductive layers.

15. The anisotropic conductive sheet according to claim 13, wherein the bonding layer is disposed to surround each of the plurality of conductive layers.

16. The anisotropic conductive sheet according to claim 13, wherein the bonding layer includes a polycondensation product of alkoxysilane or its oligomer.

17. The anisotropic conductive sheet according to claim 13,
wherein the bonding layer comprises a third resin composition; and
wherein a glass transition temperature of the third resin composition is higher than a glass transition temperature of the first resin composition.

18. The anisotropic conductive sheet according to claim 17, wherein the glass transition temperature of the third resin composition is 150° C. or above.

19. The anisotropic conductive sheet according to claim 1,
wherein the insulation layer includes:
a first insulation layer including the first surface, and comprising the first resin composition, and
a second insulation layer including the second surface, and comprising a fourth resin composition;
wherein a probe tack value at 25° C. of the second surface of the second insulation layer is higher than a probe tack value of the first surface of the first insulation layer, the probe tack value being a value that is measured in accordance with ASTM D2979:2016; and
wherein the probe tack value of the second insulation layer is 3N/5 mmφ or greater.

20. The anisotropic conductive sheet according to claim 19, wherein a storage modulus of the fourth resin composition at 25° C. is lower than a storage modulus of the first resin composition at 25° C.

21. The anisotropic conductive sheet according to claim 19, wherein a storage modulus of the fourth resin composition is 1.0×10⁴ to 1.0×10⁶ Pa.

22. The anisotropic conductive sheet according to claim 19, wherein a glass transition temperature of the fourth resin composition is lower than a glass transition temperature of the first resin composition.

23. The anisotropic conductive sheet according to claim 22, wherein the glass transition temperature of the fourth resin composition is −40° C. or below.

24. The anisotropic conductive sheet according to claim 19, wherein a ratio T1/T2 of a thickness T1 of the first insulation layer and a thickness T2 of the second insulation layer is 4/6 to 9/1.

25. The anisotropic conductive sheet according to claim 19, wherein G2/(G1+G4) is 9.0 to 9.0×10⁴, where G1 is a storage modulus of the first resin composition at 25° C., G2 a storage modulus of the second resin composition at 25° C., and G4 a storage modulus of the fourth resin composition at 25° C.

26. The anisotropic conductive sheet according to claim 19, wherein G2/G1 is 10.0 to 1.0×10⁵, and/or G2/G4 is 1.0×10² to 1.0×10⁶, where G1 is a storage modulus of the first resin composition at 25° C., G2 a storage modulus of the second resin composition at 25° C., and G4 a storage modulus of the fourth resin composition at 25° C.

27. The anisotropic conductive sheet according to claim 1, wherein an area of an end surface of each of the plurality of columnar resins on a first surface side is smaller than an area of an end surface of each of the plurality of columnar resins on a second surface side.

28. The anisotropic conductive sheet according to claim 1, wherein a center-to-center distance of the plurality of columnar resins on a first surface side is 5 to 55 μm.

29. The anisotropic conductive sheet according to claim 1,
wherein the anisotropic conductive sheet is configured to be used for an electrical testing of an inspection object; and
the inspection object is disposed on the first surface.

30. An electrical testing apparatus, comprising:
an inspection substrate including a plurality of electrodes; and
the anisotropic conductive sheet according to claim 1 disposed on a surface of the inspection substrate where the plurality of electrodes is disposed.

31. An electrical testing method, comprising:
stacking an inspection substrate including a plurality of electrodes and an inspection object including a terminal through the anisotropic conductive sheet according to claim 1 to electrically connect the plurality of electrodes of the inspection substrate and the terminal of the inspection object through the anisotropic conductive sheet.
